(19) United States
(12) Patent Application Publication
(10) Pub. No.: US 2008/0259703 A1
(43) Pub. Date: Oct. 23, 2008

(54) SELF-TIMED SYNCHRONOUS MEMORY

(75) Inventor: Onur Ozbek, Lynnwood, WA (US)

Correspondence Address: Stolowitz Ford Cowger, LLP/Cypress, 621 Sw Morrison St., Suite 600, Portland, OR, 97205, US

(73) Assignee: Cypress Semiconductor Corp., San Jose, CA (US)

(21) Appl. No.: 11/967,240

(22) Filed: Dec. 30, 2007

Related U.S. Application Data
(60) Provisional application No. 60/912,399, filed on Apr. 17, 2007.

(51) Int. Cl. G11C 29/00; G11C 7/00

(52) U.S. Cl. 365/201; 365/205

(57) ABSTRACT

A memory device includes a memory array having a plurality of memory cells arranged in a row-column format, where the memory array is configured to designate at least one of the memory cells as a test memory cell. The memory system also includes a sense amplifier to read the test memory cell and to evaluate a validity of the memory array responsive to reading the test memory cell.

### RELATED APPLICATIONS

This application claims the benefit of U.S. Provisional Application No. 60/912,399, filed Apr. 17, 2007, which is incorporated herein by reference.

### TECHNICAL FIELD

This disclosure relates generally to memory devices, and more particularly to testing memory cells in a memory array.

### BACKGROUND

Many memory devices, such as read-only memory (ROM) devices, include an array of memory cells arranged in a matrix of rows and columns. Most conventional approaches to testing these memory devices require inspecting or evaluating each memory cell, under various array configurations, to ensure they all work properly. For instance, when evaluating memory cells in a ROM device, sense amplifiers iteratively apply a sense current to each memory cell in the array and determine whether the stored bit of data can be read properly within an appropriate period of time.

Since the location of the memory cell in the array can introduce delay during read operations, for example, due to the cumulative resistance and gate capacitance along the rows and cumulative drain capacitance along the columns in the ROM devices, memory cells at various locations of the array will respond differently to the evaluation process. Further, the logic state, i.e., “1” or “0”, stored by ROM memory cells can introduce additional delay along the columns of the array, for example, by providing additional cumulative drain capacitance. Thus, conventionally, each memory device is typically evaluated or tested for various configurations of the array, i.e., with varying logic states for memory cells surrounding the memory cell under evaluation. These conventional testing techniques are often time consuming and undesirable due to large power consumption by the sense currents when the test is run on chip during operation.

### SUMMARY

A device comprising a memory array including a plurality of memory cells arranged in a row-column format, where the memory array is configured to designate at least one of the memory cells as a test memory cell, and a sense amplifier to read the test memory cell and to evaluate a validity of the memory array responsive to reading the test memory cell.

In various embodiments, the memory array includes a test row of memory cells and a test column of memory cells, where the test memory cell is located at an intersection of the test row and the test column. The device including a word line decoder to activate a test word line corresponding to the test row of memory cells in the memory array, where the test memory cell receives the activation of test word line after the other memory cells in the test row of memory cells. The sense amplifier is operable to apply a test sense current through a test bit line corresponding to the test column of memory cells in the memory array, where the test memory cell receives the test sense current with an associated capacitance accumulated according to a configuration of the other memory cells in the test column. The memory cells are read only memory (ROM) cells that indicate a logical state according to a coupling to corresponding bit lines. The test memory cell is not coupled to the test bit line and has a logical state of 1, where the remaining memory cells in the test column are coupled to the test bit line and have a logical state of 0. The sense amplifier is operable to automatically shut-off the test sense current responsive to reading the test memory cell.

A method comprising reading a test memory cell in a memory array, the memory array having a plurality of memory cells arranged in a row-column format and configured to designate at least one of the memory cells as the test memory cell, and evaluating a validity of all of the memory cells in the memory array responsive to the reading the test memory cell.

In various embodiments, the reading of the test memory cell in the memory array includes activating a word line corresponding to the test memory cell, and providing a test sense current to a bit line associated with the test memory cell. The memory array includes a test row of memory cells associated with the activated word line and a test column of memory cells associated with the bit line, where the test memory cell is located at an intersection of the test row and the test column. The test memory cell receives the activation of test word line after the other memory cells in a test row of memory array, and receives the test sense current with an associated capacitance accumulated according to a configuration of the other memory cells in the test column. The method includes automatically ceasing to generate a test sense current responsive to reading the test memory cell. The method includes outputting a design for test signal indicating the validity of all of the memory cells in the memory array

A system comprising structure for reading a test memory cell in a memory array, the memory array having a plurality of memory cells arranged in a row-column format and configured to designate at least one of the memory cells as the test memory cell, and structure for evaluating a validity of all of the memory cells in the memory array responsive to the reading the test memory cell. The structure for reading the test memory cell in the memory array includes structure for activating a word line corresponding to the test memory cell and structure for providing a test sense current to a bit line associated with the test memory cell. The memory array includes a test row of memory cells associated with the activated word line and a test column of memory cells associated with the bit line, where the test memory cell is located at an intersection of the test row and the test column. The test memory cell receives the activation of test word line after the other memory cells in a test row of memory array, and receives the test sense current with an associated capacitance accumulated according to a configuration of the other memory cells in the test column. The system includes structure for automatically ceasing to generate a test sense current responsive to reading the test memory cell. The system includes structure for outputting a design for test signal indicating the validity of all of the memory cells in the memory array. The design for test signal can also be used to turn off the power to the system under the assumption that all of the memory cells in the memory array have been evaluated with the evaluation of the worst-case scenario indicated by the design for test signal. The memory cells are read only memory (ROM) cells that indicate a logical state according to a coupling to corresponding bit lines.

### DESCRIPTION OF THE DRAWINGS

The invention may be best understood by reading the disclosure with reference to the drawings.

FIG. 1 is a block diagram of a memory system according to embodiments of the invention.

FIG. 2 is a block diagram illustrating embodiments of a memory array within the memory system shown in FIG. 1.

FIGS. 3A-3B are schematic diagrams illustrating embodiments of memory cells within the memory system shown in FIG. 2.

FIG. 3C is a schematic diagram illustrating an example configuration of the test portions of the memory array shown in FIG. 2.

FIG. 4 is a schematic diagram illustrating embodiments of sense amplifiers within the memory system shown in FIG. 1.

FIG. 5 is a flowchart illustrating example embodiments of the memory system shown in FIG. 1.

### DETAILED DESCRIPTION

By dedicating specific portions of the memory array for testing the operation of the memory system, i.e., a test row and a test column, and intelligently configuring them to mimic a “worst-case” scenario for a test memory cell, embodiments of the invention can evaluate the validity of the entire memory array by testing the validity of the test memory cell under the “worst-case” scenario. Embodiments are shown and described below in greater detail.

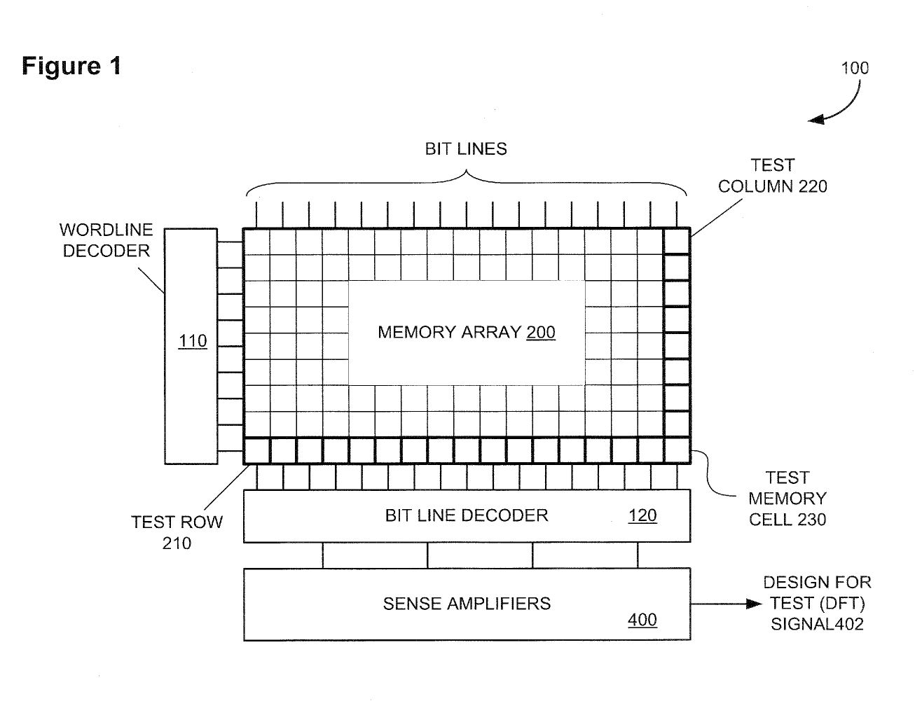

FIG. 1 is a block diagram of a memory system 100 according to embodiments of the invention. Referring to FIG. 1, the memory system 100 includes a memory array 200 having a plurality of memory cells arranged in a row-column format. In some embodiments, each memory cell can store a bit of data, for example, when they are read-only memory (ROM) cells.

The memory system 100 includes a word line decoder 110 to activate at least one of a plurality of word lines corresponding to rows of the memory array 200. The word line decoder 110 can receive instructions, for example, from a memory controller (not shown), that indicate which word line is to be activated. In some embodiments, the word lines decoder 110 can be a multiplexer that decodes an input to activate corresponding word lines.

The memory system 100 includes sense amplifiers 400 to generate sense current applied to at least one of a plurality of bit lines corresponding to columns of the memory array 200. In some embodiments, the memory system 100 can include a bit line decoder 120 to receive sense current from the bit lines and provide the sense current to the sense amplifiers 400. Embodiments of the sense amplifiers 400 will be described below in greater detail.

When reading data stored in the memory cells, the word line decoder 110 activates a row of the memory array 200 that includes the memory cell to be read, and the sense amplifiers 400 can provide a sense current to a column of the memory array 200 that includes the memory cell to be read. The sense amplifiers 400 can read the memory cell to determine its logical state according to the sense current received from the bit line, that has propagated through the memory array 200 and optionally the bit line decoder 120.

The memory array 200 includes a dedicated test row 210 and a dedicated test column 220 that can be configured to evaluate test memory cell 230, such that a determination of its validity establishes a high probability that the all of the memory cells in the memory array 200 are operating properly. The sense amplifiers 400 can output a design for test signal 402 that indicates the results of the test on test memory cell 230. The design for test signal 402 can prompt a shutting off of the power to the memory system 100, since once the test memory cell 230 has been evaluated the entire memory array is deemed to have been evaluated. By shutting off the power to the memory system 100 after evaluating the test memory cell 230, the memory system 100 can reduce power consumption compared with conventional memory devices that require testing of each memory cell in an array under various configurations. Embodiments of these dedicated test regions of memory array will now be described in greater detail.

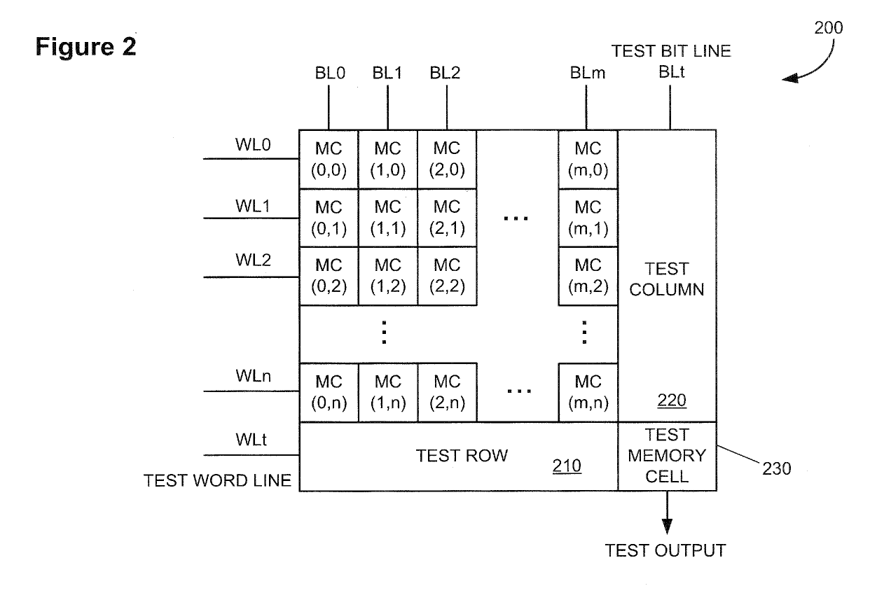

FIG. 2 is a block diagram illustrating embodiments of a memory array within the memory system shown in FIG. 1. Referring to FIGS. 1 and 2, the memory array 200 includes a plurality of memory cells MC arranged in an n-by-m matrix, where n and m are positive integers. For instance, memory cell MC(0,0) indicates the memory cell is located in column 0 and row 0, while memory cell MC(m,n) indicates the memory cell is located in column m and row n.

The memory array 200 includes a dedicated test row 210 and a dedicated test column 220. The test row 210 can include a plurality of memory cells, where the test memory cell 230 is located farthest away from the word line decoder 110 and is last memory cell to be activated by a corresponding test word line WLt. This location allows the test memory cell 230 to see the largest resistance and gate capacitance when receiving voltage from the word line decoder 110, and thus undergo a delay that is the longest or substantially as long in duration as other memory cells MC in the memory array 200.

The test column 220 can include a plurality of memory cells, where the test memory cell 230 is located at the bottom of the memory array 200, i.e., so the test memory cell 230 is the last memory cell along the test bit line BLt capable of receiving a sense current. Thus, the test memory cell 230 can see the largest drain capacitance from the other memory cells in the test column 220 when receiving a sense current. The amount of the drain capacitance corresponds to the delay during read operations. In some embodiments, the memory cells in the test column 220 can be have an increased drain capacitance associated with the read operations when they are configured to store a logical state of 0.

The test memory cell 230 is located in the test row 210 and the test column 220 to have the largest resistance and capacitances of any memory cell MC in the memory array 200, and thus mimic a worst case scenario for the memory array 200 during read operations. In some embodiments, the sense amplifiers 400 can be further configured to attenuate this worst case scenario by reducing the sense current applied to the test bit line BLt. Since reducing the sense current, for example, by 25%, causes additional delay and difficulty in determining whether the test memory cell 230 is still operational with an adequate response time.

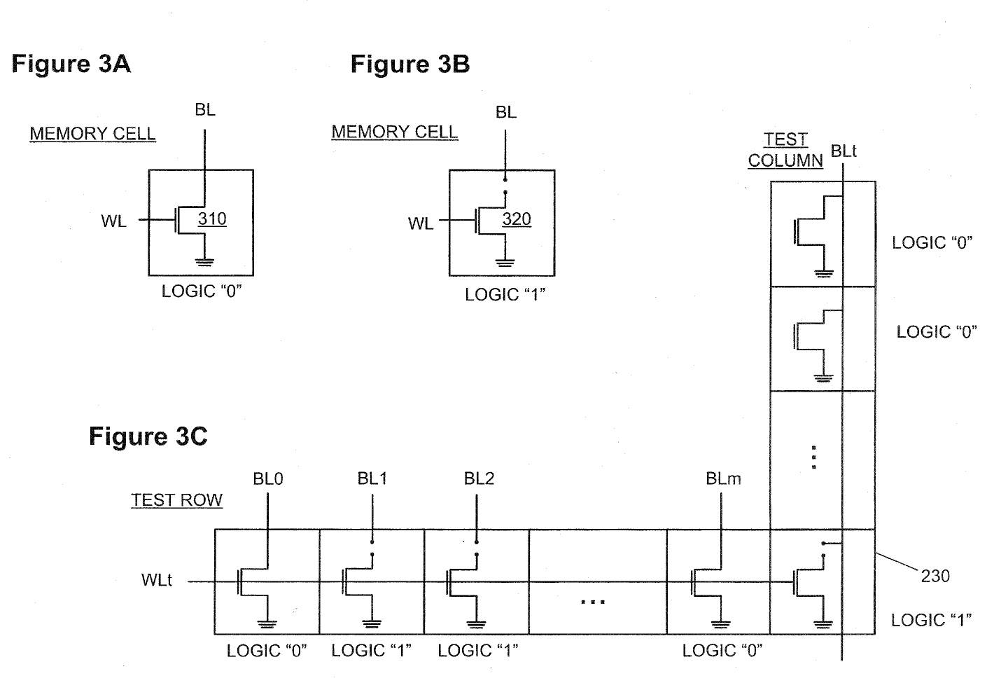

FIGS. 3A-3B are schematic diagrams illustrating embodiments of memory cells MC within the memory system 100 shown in FIG. 2. Referring to FIGS. 3A and 3B, the memory cells MC shown read only memory (ROM) cells configured with a logic 0 and logic 1, respectively. The logic 0 memory cell includes a single transistor 310, for example, an NMOS transistor, which has a gate coupled to a word line WL, a source coupled to ground, and a drain coupled to a bit line BL. During a read operation, the transistor 310 is activated by the word line WL, thus drawing a sense current applied to the bit line BL towards the ground and dropping a drain voltage. The sense amplifiers 400 detect this voltage drop associated with the drain of the transistor 310 and output a logic 0 signal corresponding to that memory cell. In some embodiments, when the sense amplifiers 400 provide excess of sense current to the transistor 310, the characteristics of the transistor 310 can elevate a voltage associated with the drain, which can possibly cause the sense amplifiers 400 to mis-detect the logic state of the memory cell. Thus, the sense amplifiers 400 should be calibrated to not provide too much sense current to memory cells during read operations.

The logic 1 memory cell includes a single transistor 320, for example, an NMOS transistor, which has a gate coupled to a word line WL, a source coupled to ground, and a drain is not coupled to a bit line BL. During a read operation, since the drain of the transistor 320 is floating, the transistor 320 does not draw the sense current applied to the bit line BL towards the ground, thus leaving the voltage associated with the bit line substantially unchanged. The sense amplifiers 400 detect the lack of change in the bit line voltage and output a logic 1 signal corresponding to that memory cell.

FIG. 3C is a schematic diagram illustrating an example configuration of the test portions of the memory array 200 shown in FIG. 2. Referring to FIG. 3C, the test row 210 and the test column 220 can be configured to provide a worst case scenario for the test memory cell 230. The test memory cell 230 can be set to logic 1, as this configuration is more difficult for the sense amplifiers to ascertain. In some embodiments, the test row 210 can have memory cells set to either have a logic of 0 or a logic of 1, since both types of memory cells provide substantially the same resistance and gate capacitance when viewed from the test memory cell 230. Since memory cells with a logic of 0 introduce a drain capacitance to the corresponding bit line, the test column 220 can have each of its memory cells MC configured as logic 0, allowing the greatest delay to be incurred when reading test memory cell 230.

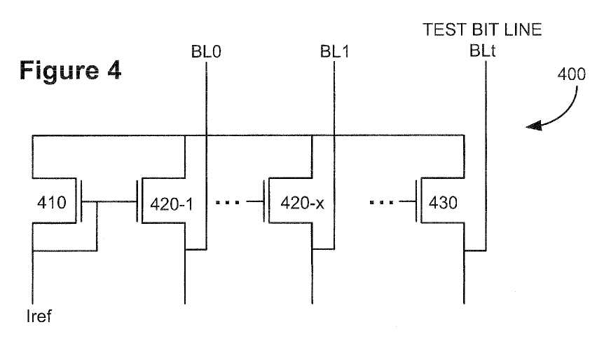

FIG. 4 is a schematic diagram illustrating embodiments of sense amplifiers 400 within the memory system 100 shown in FIG. 1. Referring to FIG. 4, the sense amplifiers 400 can include a current mirror 410 that has an associated reference current Iref. The sense amplifiers 400 can be transistors 420-1 to 420-x and 430 that replicate a multiple of the reference current Iref according to the characteristics of the transistors. For instance, in some embodiments, the transistors 420-1 to 420-x can replicate double the reference current Iref. In some embodiments, the test sense amplifier 430 can replicate one and a half times the reference current Iref to further attenuate the worst case scenario for the test memory cell 230. Once the test memory cell 230 has been evaluated by the system the sense amplifiers 400 can shut-off the test sense amplifier 430, or cause it to cease operating, thus reducing current consumption in the memory system 100.

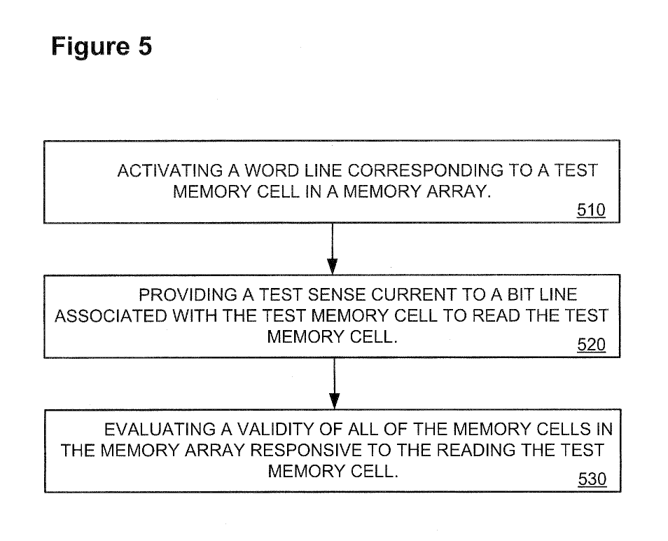

FIG. 5 is a flowchart illustrating example embodiments of the memory system 100 shown in FIG. 1. Referring to FIG. 5, at a block 510, the memory system 100 activates a word line corresponding to a test memory cell in a memory array. The test word line can be activated when the memory system 100 is in a test mode and attempting to evaluate the test memory cell 230. The activation of the test word line can be propagated to the test memory cell 230 through a plurality of other memory cells within a test row 210 of the memory array 200. Each additional memory cell included in the test row 210 adds to the total or cumulative resistance and capacitance on the word line, when viewed from the test memory cell 230, thus further delaying a read operation.

At a block 520, the memory system 100 applies a test sense current to a bit line associated with the test memory cell 230 to read the test memory cell 230. The sense amplifiers 400 can apply a test sense current to a test column 220 that includes the test memory cell 230, where each memory cell having a logical state of 0 increases a cumulative drain capacitance of along the bit line. This subsequently will delay the read operation of the test memory cell 230 and possibly can make it difficult for the sense amplifiers to detect the configuration of the test memory cell.

In some embodiments, the sense amplifiers 400, particularly a test sense amplifier 430, can provide less current during the test mode than is applied during regular read operations of other memory cells in the memory array 200. Once the test memory cell 230 is read by the sense amplifiers 400, they can turn-off the test sense amplifier 430 and reduce power consumption of the memory system 100.

At a block 530, the memory system 100 evaluates a validity of all of the memory cells in the memory array responsive to the reading the test memory cell. The memory system 100 can generate and output a design for test signal 140 that indicates the results of the test of the test memory cell 230. When the test memory cell 230 passes the test, there is a high probability that the other memory cells in the memory array 200 are valid. In other words, since the memory array 200 is configured to place the test memory cell 230 in a worst case scenario, which is further attenuated by reducing a sense current used to read the test memory cell 230, if the sense amplifiers 400 can properly read the test memory cell 230 then they can most likely read the other memory cells in the memory array 200.

One of skill in the art will recognize that the concepts taught herein can be tailored to a particular application in many other advantageous ways. In particular, those skilled in the art will recognize that the illustrated embodiments are but one of many alternative implementations that will become apparent upon reading this disclosure.

The preceding embodiments are exemplary. Although the specification may refer to “an”, “one”, “another”, or “some” embodiment(s) in several locations, this does not necessarily mean that each such reference is to the same embodiment(s), or that the feature only applies to a single embodiment.

1. A device comprising:
a memory array including a plurality of memory cells arranged in a row-column format, where the memory array is configured to designate at least one of the memory cells as a test memory cell; and
a sense amplifier to read the test memory cell and to evaluate a validity of the memory array responsive to reading the test memory cell.

2. The device of claim 1 where the memory array includes a test row of memory cells and a test column of memory cells, where the test memory cell is located at an intersection of the test row and the test column.

3. The device of claim 2 including a word line decoder to activate a test word line corresponding to the test row of memory cells in the memory array, where the test memory cell receives the activation of test word line after the other memory cells in the test row of memory cells.

4. The device of claim 2 where the sense amplifier is operable to apply a test sense current through a test bit line corresponding to the test column of memory cells in the memory array, where the test memory cell receives the test sense current with an associated capacitance accumulated according to a configuration of the other memory cells in the test column.

5. The device of claim 4 where the memory cells are read only memory (ROM) cells that indicate a logical state according to a coupling to corresponding bit lines.

6. The device of claim 5 where the test memory cell is not coupled to the test bit line and has a logical state of 1, where the remaining memory cells in the test column are coupled to the test bit line and have a logical state of 0.

7. The device of claim 1 where the sense amplifier is operable to automatically shut-off the test sense current responsive to reading the test memory cell.

8. A method comprising:
reading a test memory cell in a memory array, the memory array having a plurality of memory cells arranged in a row-column format and configured to designate at least one of the memory cells as the test memory cell; and
evaluating a validity of all of the memory cells in the memory array responsive to the reading the test memory cell.

9. The method of claim 8 where reading the test memory cell in the memory array includes:
activating a word line corresponding to the test memory cell; and
providing a test sense current to a bit line associated with the test memory cell.

10. The method of claim 9 where the memory array includes a test row of memory cells associated with the activated word line and a test column of memory cells associated with the bit line, where the test memory cell is located at an intersection of the test row and the test column.

11. The method of claim 10 where the test memory cell receives the activation of test word line after the other memory cells in a test row of memory array, and receives the test sense current with an associated capacitance accumulated according to a configuration of the other memory cells in the test column.

12. The method of claim 8 includes automatically ceasing to generate a test sense current responsive to reading the test memory cell.

13. The method of claim 12 includes outputting a design for test signal indicating the validity of all of the memory cells in the memory array

14. A system comprising:
structure for reading a test memory cell in a memory array, the memory array having a plurality of memory cells arranged in a row-column format and configured to designate at least one of the memory cells as the test memory cell; and
structure for evaluating a validity of all of the memory cells in the memory array responsive to the reading the test memory cell.

15. The system of claim 14 where the structure for reading the test memory cell in the memory array include:
structure for activating a word line corresponding to the test memory cell; and
structure for providing a test sense current to a bit line associated with the test memory cell.

16. The system of claim 15 where the memory array includes a test row of memory cells associated with the activated word line and a test column of memory cells associated with the bit line, where the test memory cell is located at an intersection of the test row and the test column.

17. The system of claim 16 where the test memory cell receives the activation of test word line after the other memory cells in a test row of memory array, and receives the test sense current with an associated capacitance accumulated according to a configuration of the other memory cells in the test column.

18. The system of claim 14 includes structure for automatically ceasing to generate a test sense current responsive to reading the test memory cell.

19. The system of claim 18 includes structure for outputting a design for test signal indicating the validity of all of the memory cells in the memory array.

20. The system of claim 14 where the memory cells are read only memory (ROM) cells that indicate a logical state according to a coupling to corresponding bit lines.
